(19) United States
(12) Patent Application Publication
(10) Pub. No.: US 2009/0035705 A1
(43) Pub. Date: Feb. 5, 2009

(54) METHOD OF FORMING PATTERN, METHOD OF MANUFACTURING SEMICONDUCTOR DEVICE, AND CLEANING APPARATUS

(76) Inventor: Shinichi ITO, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/179,753

(22) Filed: Jul. 25, 2008

(30) Foreign Application Priority Data
Jul. 30, 2007 (JP) 2007-197795

(51) Int. Cl. G03F 7/20; B08B 3/04

(52) U.S. Cl. 430/319; 430/325; 134/155; 134/58 R

(57) ABSTRACT

A method of forming a pattern includes forming a resist layer on a substrate, cleaning a surface of the substrate under a control that a shear stress acting on an interface between a cleaning liquid and the substrate during the cleaning becomes larger than a shear stress acting on an interface between an immersion liquid and the substrate during immersion exposure, exposing the resist layer by the immersion exposure to form a latent image on the resist layer, and developing the resist layer to form a resist pattern on the substrate.

### CROSS REFERENCE TO RELATED APPLICATION

This application is based upon and claims the benefit of priority from the prior Japanese Patent Application No. 2007-197795, filed on Jul. 30, 2007, the entire contents of which are incorporated herein by reference.

### BACKGROUND OF THE INVENTION

1. Field of the Invention

The present invention relates to a method of forming a pattern, a method of manufacturing a semiconductor device, and a cleaning apparatus.

2. Background Art

A circuit pattern of a semiconductor device tends to be miniaturized year by year. For this reason, there is a need for an improved exposure machine. At present, an exposure machine whose light source is an ArF laser of 193-nm wavelength is widely used in mass production and development as an advanced exposure machine.

A medium that occupies an optical path between a projection lens of an exposure machine and a resist layer to be exposed is called an optical path medium. A known exposure method is an immersion exposure method in which the optical path medium is a liquid. In immersion exposure, the numerical aperture of a projection light can be increased by increasing the refractive index of the optical path medium. This makes it possible to form a fine circuit pattern that exceeds the limit of usual exposure in which the optical path medium is air. Immersion exposure is generally classified into a method in which a whole substrate surface is immersed in the optical path medium, and a method in which only a part of a substrate surface around the optical path is locally immersed in the optical path medium. At present, immersion exposure machines such as using the latter method are actively developed.

An important characteristic required to the optical path medium is high transparency at exposure wavelength. For an immersion exposure machine including a 193-nm light source, ultrapure water having a refractive index of approximately 1.43 is considered to be the most promising candidate optical path medium. Further, organic chemical liquids having higher refractive indices are being developed.

In immersion exposure, it is feared that problems may occur due to the contact of the optical path medium and the resist layer. For example, there is a possibility that contaminations such as photoacid generators present on the surface of the resist layer dissolve in the optical path medium by the contact of the resist layer and the optical path medium. Furthermore, when such an optical path medium remains on an exposure stage, there is a possibility that contaminations dissolved in the optical path medium adhere to the exposure stage to be a pollution source.

Japanese Patent No. 3857692 discloses a method of forming a pattern, the method including steps of forming a chemically amplified resist layer on a substrate to be processed, removing photoacid generators that segregate in a surface layer of the resist layer, with a cleaning liquid that contains any one or more of pure water, ozone water, and hydrogen peroxide water, radiating an energy ray in a certain position of the resist layer to form a latent image in the resist layer, and developing the resist layer to form a chemically amplified resist pattern based on the latent image. Japanese Patent No. 3857692 further discloses a method of forming a pattern, wherein the step of radiating the energy ray is performed by immersion exposure via a water layer formed in an optical path between the resist layer and an optical system of a projection exposure apparatus. This method is effective in coping with the above described problems.

JP-A No. 2005-294520 (KOKAI) discloses a method of cleaning a substrate surface by supplying a cleaning liquid to the substrate surface from a cleaning liquid nozzle, with holding the substrate by a substrate holding section. The cleaning of the substrate surface by this method is intended for preventing substances such as photoacid generators adhered to the substrate surface from being carried into an exposure apparatus, and the inside of the exposure apparatus (e.g., an exposure stage) from being contaminated. However, if the impact given by the cleaning liquid to the substrate surface during the cleaning is small, there is a possibility that the substrate surface is washed with an immersion liquid during immersion exposure, and the exposure apparatus is contaminated with washed substances.

JP-A No. 2005-353763 (KOKAI) discloses an exposure apparatus including a cleaning section that cleans the surface of a resist layer formed on a wafer, and an exposure unit that performs pattern exposure with disposing a liquid between the resist layer and an exposure lens. JP-A No. 2005-353763 (KOKAI) further discloses an exposure apparatus further including first and second stages, each of which is capable of holding the wafer on a top surface, one of the first and second stages being included in the exposure unit, and the other being included in the cleaning section.

### SUMMARY OF THE INVENTION

An aspect of the present invention is, for example, a method of forming a pattern, the method including forming a resist layer on a substrate, cleaning a surface of the substrate under a control that a shear stress acting on an interface between a cleaning liquid and the substrate during the cleaning becomes larger than a shear stress acting on an interface between an immersion liquid and the substrate during immersion exposure, exposing the resist layer by the immersion exposure to form a latent image on the resist layer, and developing the resist layer to form a resist pattern on the substrate.

Another aspect of the present invention is, for example, a method of manufacturing a semiconductor device, the method including forming a resist layer on a substrate, cleaning a surface of the substrate under a control that a shear stress acting on an interface between a cleaning liquid and the substrate during the cleaning becomes larger than a shear stress acting on an interface between an immersion liquid and the substrate during immersion exposure, exposing the resist layer by the immersion exposure to form a latent image on the resist layer, developing the resist layer to form a resist pattern on the substrate, and processing, using the resist pattern, the substrate or/and a layer to be processed existing between the substrate and the resist pattern.

Another aspect of the present invention is, for example, a cleaning apparatus including a cleaning jig for cleaning a surface of a substrate with a cleaning liquid, a cleaning liquid supplying section provided in the cleaning jig and configured to supply the cleaning liquid, a cleaning liquid removing section provided in the cleaning jig and configured to remove the cleaning liquid, and a cleaning control section configured to clean the surface of the substrate, by relatively moving the substrate and the cleaning jig under a condition that the cleaning liquid exists between the substrate and the cleaning jig.

### BRIEF DESCRIPTION OF THE DRAWING

FIGS. 1A to 1D are side sectional views of a substrate before cleaning;

FIG. 2 is a top view showing the substrate during immersion exposure;

FIG. 3 is a top view showing an exposure map;

FIGS. 4A and 4B are side sectional views of the substrate after immersion exposure;

FIGS. 5X and 5Y are a side view and a top view of an immersion exposure machine;

FIGS. 6X and 6Y are a side view and a top view of a cleaning machine;

FIG. 7 is a top view showing the substrate during cleaning;

FIG. 8 is a top view for explaining the moving speed of a cleaning jig;

FIGS. 9A and 9B are cross-sectional views of the substrate after development; and

FIGS. 10A and 10B are cross-sectional views of the substrate after etching process.

### DESCRIPTION OF THE EMBODIMENTS

Embodiments of the present invention will be described below with reference to the accompanying drawings.

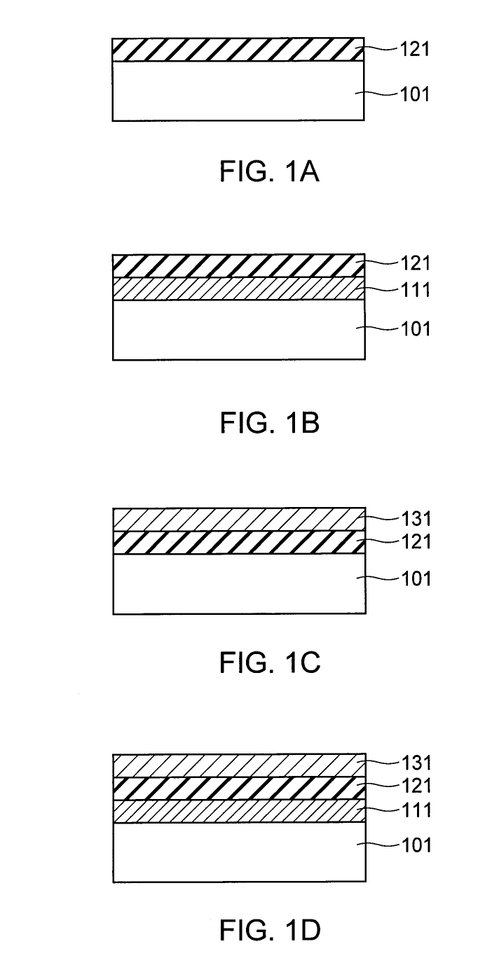

FIGS. 1A to 1D are cross-sectional views of a substrate (wafer substrate) 101. In a pattern forming method of the present embodiment, first, a resist layer 121 is formed on the substrate 101 as shown in any of FIGS. 1A to 1D. The substrate 101 may be a bulk semiconductor substrate or an SOI (semiconductor on insulator) substrate. The resist layer 121 in this embodiment is a chemically amplified resist layer, but it may be a resist layer other than a chemically amplified resist layer.

In FIG. 1A, the resist layer 121 is formed directly on the substrate 101. In the case of FIG. 1A, the resist layer 121 is used in processing the substrate 101. In FIG. 1B, the resist layer 121 is formed on the substrate 101 via a layer (such as antireflection layer) 111 to be processed. In the case of FIG. 1B, the resist layer 121 is used in processing the layer 111. The resist layer 121 in FIG. 1B may be used in processing the layer 111 and the substrate 101. In the case of FIG. 1A or 1B, the resist layer 121 is exposed on the surface of the substrate 101. That is, the surface of the substrate 101 is formed by the resist layer 121. The layer 111 may be a single layer including one layer or a stacked layer including two or more layers.

In FIG. 1C, a cover layer 131 is formed on the resist layer 121 of FIG. 1A. In the case of 1C, the resist layer 121 is used in processing a substrate 101. In FIG. 1D, the cover layer 131 is formed on the resist layer 121 of FIG. 1B. In the case of FIG. 1D, the resist layer 121 is used in processing a layer 111. The resist layer 121 in FIG. 1D may be used in processing both the layer 111 and the substrate 101. In the case of 1C or 1D, the cover layer 131 is exposed on the surface of the substrate 101. That is, the surface of the substrate 101 is formed by the cover layer 131. The cover layer 131 is an example of an application layer. The cover layer 131 may be a single layer including one layer or a stacked layer including two or more layers.

There may be one or more layers between the substrate 101 and the layer 111 to be processed. Examples of such layers include a layer already processed, an etching stopper, and a stress liner. Further, there may be one or more layers between the layer 111 to be processed and the resist layer 121. Examples of such layers include an organic resin layer for planarizing irregularities on the surface of the layer 111, a carbon CVD layer used as a mask for processing, an amorphous silicon layer, and a SOG layer. Such layers may exist between the substrate 101 and the resist layer 121 in the case of FIG. 1A or 1C. Examples of the layer 111 to be processed include a gate electrode layer, a contact plug layer, a via plug layer, a line layer, and an inter layer dielectric.

Description of the pattern forming method of this embodiment will be continued. Regarding the substrate 101 in the following description, it is supposed that processes such as forming the layer 111, forming the resist layer 121, and forming the cover layer 131 have been already carried out. In the following pattern formation, processes such as cleaning, immersion exposure, and development of the substrate 101 are carried out.

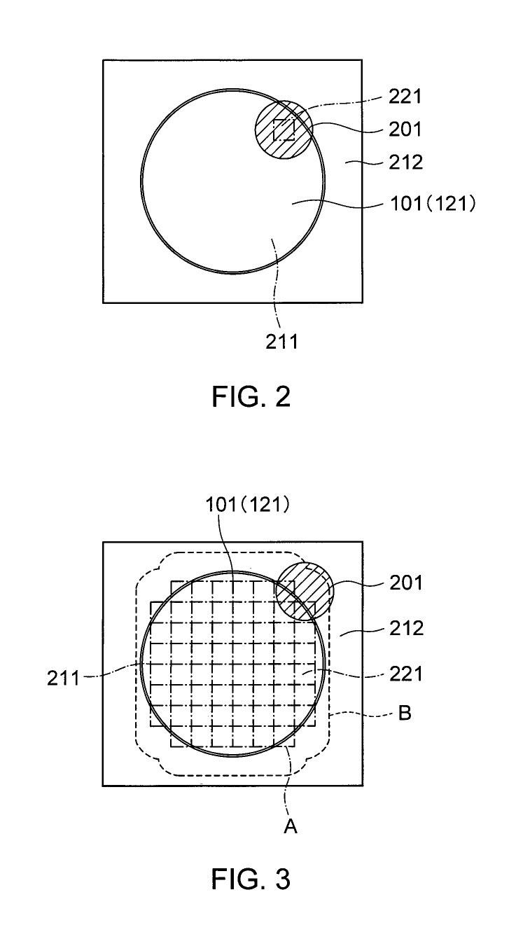

FIG. 2 is a top view showing the substrate 101 during immersion exposure. Immersion exposure adopted in this embodiment is a method in which only a part of the substrate surface around an optical path is locally immersed in an optical path medium (immersion liquid). However a method in which the whole substrate surface is immersed in an optical path medium (immersion liquid) may be adopted. FIG. 2 shows an immersion region 201 which is locally immersed in an immersion liquid during immersion exposure. The immersion liquid in this embodiment is pure water, for example, ultrapure water having a refractive index of approximately 1.43 (at 193 nm).

There is an immersion exposure stage 211 just under the substrate 101, and the substrate 101 is held on the immersion exposure stage 211. In FIG. 2, the immersion exposure stage 211 is hidden behind the substrate 101. When a peripheral portion of the substrate 101 is exposed, the immersion region 201 protrudes to outside the substrate 101. Therefore, an auxiliary immersion stage 212 is disposed around the substrate 101. This ensures that the immersion region 201 is not disturbed in the outside of the substrate 101.

Further, FIG. 2 shows an exposure region 221 where an energy ray is radiated during immersion exposure. The energy ray in this embodiment is a laser beam, for example, an ArF laser beam of 193 nm wavelength. The exposure region 221 of FIG. 2 is positioned in a peripheral portion of the substrate 101. Therefore, the immersion region 201 of FIG. 2 protrudes to outside the substrate 101. However, because the auxiliary immersion stage 212 is disposed around the substrate 101, it is ensured that the immersion liquid does not flow out of the immersion region 201.

In FIG. 3, an exposure map showing the position of each exposure region 221 is indicated by broken lines A. Furthermore, in FIG. 3, a region with which the immersion region 201 comes into contact at least once during the immersion exposure based on the exposure map is indicated by a dotted line B. The dotted line B corresponds to a border line between a contact area of the immersion region and a noncontact area of the immersion region. It is apparent that the dotted line B of FIG. 3 is positioned on the auxiliary immersion stage 212. Therefore, according to the immersion exposure based on the exposure map of FIG. 3, the whole substrate surface comes into contact with the immersion region 201 at least once. That is, the whole surface of the substrate 101 is washed with the immersion liquid.

The immersion exposure process of this embodiment is carried out as follows. First, an immersion region 201 is formed at a certain position above the substrate 101. In the case of FIG. 1A or 1B, the immersion region 201 is formed at a certain position on the resist layer 121. In the case of FIG. 1C or 1D, the immersion region 201 is formed at a certain position on the cover layer 131. Next, an energy ray is radiated in the resist layer 121 via an immersion liquid in the immersion region 201. In this way, the resist layer 121 is exposed by immersion exposure, thereby a latent image is formed on the resist layer 121.

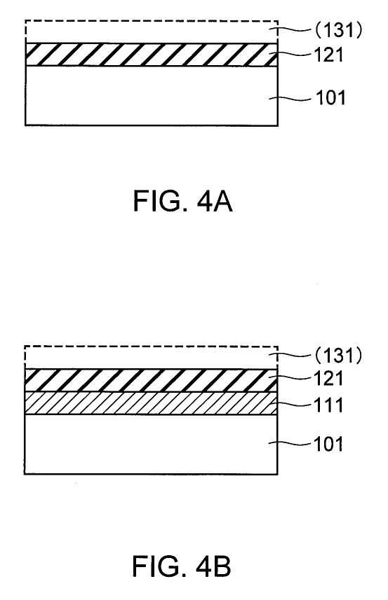

In the case of FIG. 1C or 1D, the cover layer 131 on the resist layer 121 is removed after the above-described immersion exposure. In FIG. 4A, the condition after removing the cover layer 131 from the substrate 101 of FIG. 1C is shown. In FIG. 4B, the condition after removing the cover layer 131 from the substrate 101 of FIG. 1D is shown. In the case of FIG. 1C or 1D, the cover layer 131 on the resist layer 121 is removed before/during development, which will be described later.

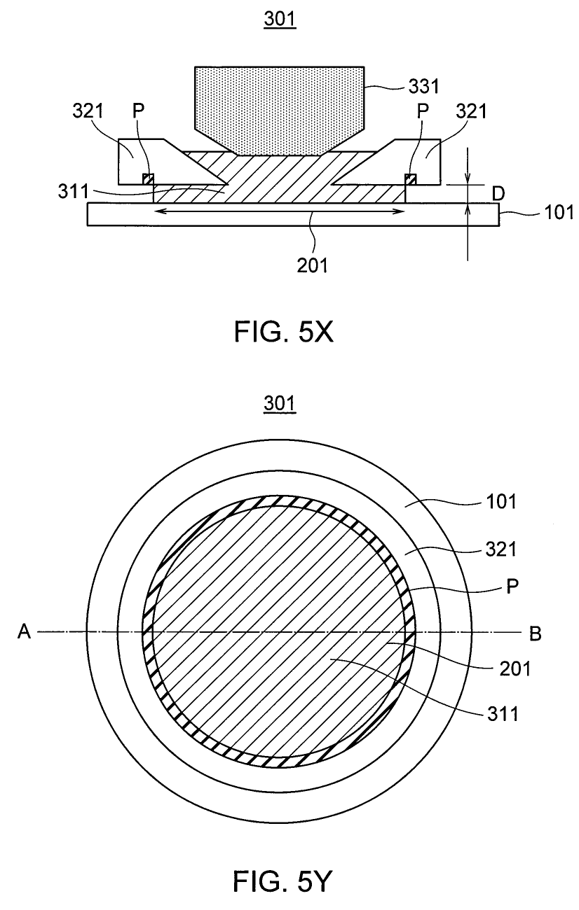

FIGS. 5X and 5Y are a side view and a top view of an immersion exposure machine (immersion exposure apparatus) 301. FIG. 5X corresponds to an A-B sectional view of FIG. 5Y. FIGS. 5X and 5Y show a substrate 101, an immersion region 201, an immersion liquid 311, an immersion exposure jig 321, and an exposure lens 331. The immersion exposure machine 301 is provided with the immersion exposure jig 321, the exposure lens 331, the immersion exposure stage 211 of FIG. 2, and the auxiliary immersion stage 212 of FIG. 2.

The immersion exposure jig 321 is provided for forming the immersion region 201 by holding the immersion liquid 311. In FIG. 5X, the immersion exposure jig 321 is disposed so as to surround the exposure lens 331. The immersion exposure jig 321 is provided with an unillustrated immersion liquid supplying section, and an immersion liquid removing section (immersion liquid suction removing section) indicated by R In FIG. 5X, the immersion liquid removing section is provided on a bottom surface of the immersion exposure jig 321. The immersion liquid 311 is supplied from the immersion liquid supplying section, and removed from the immersion liquid removing section. The flow of the immersion liquid 311 on the surface of the substrate 101 is adjusted in such a manner that the flow moves substantially from the center of the immersion region 201 toward a peripheral portion.

As shown in FIG. 5X, the immersion liquid 311 interposes between the top surface of the substrate 101 and the bottom surface of the immersion exposure jig 321. In FIG. 5X, the thickness “D” is indicated. The “D” denotes the thickness of the immersion liquid 311 existing between the substrate 101 and the immersion exposure jig 321.

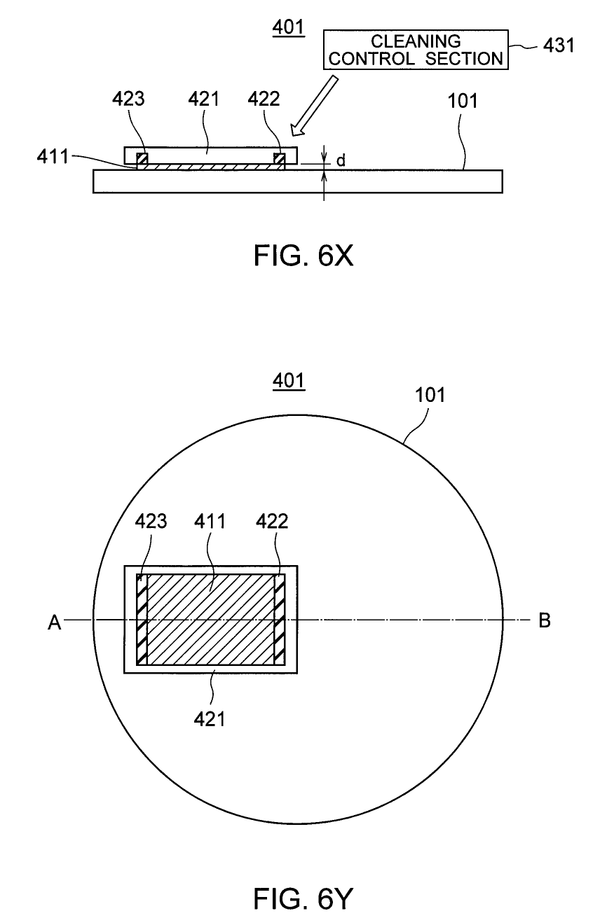

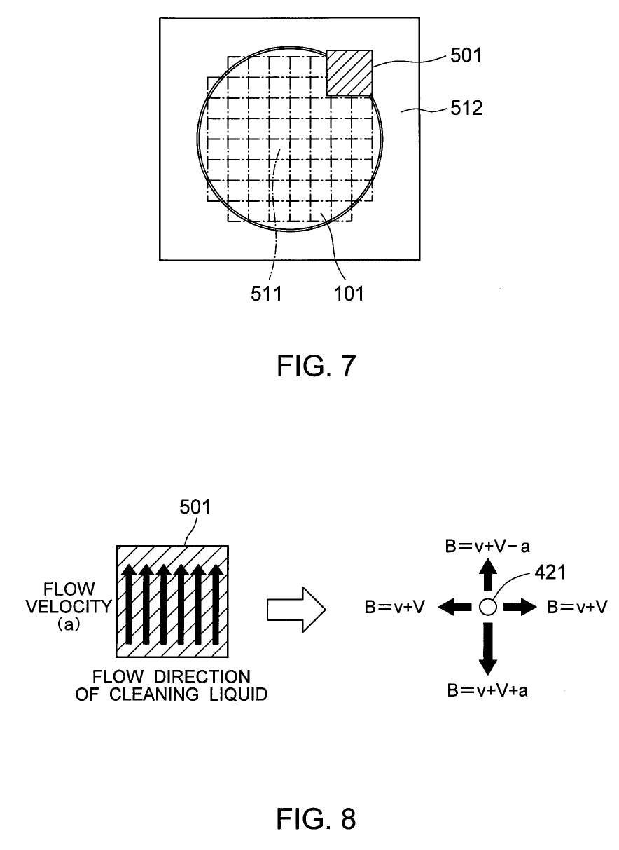

FIGS. 6X and 6Y are a side view and a top view of a cleaning machine 401. The cleaning machine 401 is an example of a cleaning apparatus. FIG. 6X corresponds to an A-B sectional view of FIG. 6Y. FIGS. 6X and 6Y show a substrate 101, a cleaning liquid 411, a cleaning jig 421, a cleaning liquid supplying section 422, a cleaning liquid removing section (cleaning liquid suction removing section) 423, and a cleaning control section 431. The cleaning machine 401 is provided with the cleaning jig 421, the cleaning liquid supplying section 422, the cleaning liquid removing section 423, the cleaning control section 431, a cleaning stage 511 of FIG. 7, and an auxiliary cleaning stage 512 of FIG. 7. The cleaning process by the cleaning machine 401 is performed before the immersion exposure process by the immersion exposure machine 301 is performed.

In FIG. 6X, the cleaning jig 421 is disposed above the substrate 101. The cleaning jig 421 is provided for cleaning the surface of the substrate 101 with the cleaning liquid 411. The cleaning jig 421 is provided, on its bottom surface, with the cleaning liquid supplying section 422 for supplying the cleaning liquid 411, and the cleaning liquid removing section 423 for removing the cleaning liquid 411. The cleaning liquid supplying section 422 and the cleaning liquid removing section 423 in this embodiment have strip-like shapes, and are disposed parallel to each other. The cleaning liquid 411 is supplied from the cleaning liquid supplying section 422, and removed from the cleaning liquid removing section 423. Thereby, the cleaning liquid 411 is supplied between the substrate 101 and the cleaning jig 421. The cleaning control section 431 is configured to control the cleaning process. The cleaning control section 431 can clean the surface of the substrate 101, by relatively moving the substrate 101 and the cleaning jig 421 under a condition that the cleaning liquid 411 exists between the substrate 101 and the cleaning jig 421.

As shown in FIG. 6X, the cleaning liquid 411 interposes between the top surface of the substrate 101 and the bottom surface of the cleaning jig 421. In FIG. 6X, the thickness “d” is indicated. The “d” denotes the thickness of the cleaning liquid 411 existing between the substrate 101 and the cleaning jig 421.

FIG. 7 is a top view showing the substrate 101 during cleaning. FIG. 7 shows a cleaning region 501 which is locally covered with the cleaning jig during cleaning. The cleaning liquid in this embodiment is the same liquid as the immersion liquid. That is, the cleaning liquid in this embodiment is pure water, for example, ultrapure water having a refractive index of approximately 1.43.

The cleaning stage 511 is present just under the substrate 101, and the substrate 101 is held on the cleaning stage 511. In FIG. 7, the cleaning stage 511 is hidden behind the substrate 101. When a peripheral portion of the substrate 101 is cleaned, the cleaning region 501 protrudes to outside the substrate 101. Therefore, the auxiliary cleaning stage 512 is disposed around the substrate 101. This ensures that the cleaning region 501 is not disturbed in the outside of the substrate 101.

The cleaning region 501 of FIG. 7 is positioned in a peripheral portion of the substrate 101. Therefore, the cleaning region 501 of FIG. 7 protrudes to outside the substrate 101. However, because the auxiliary cleaning stage 512 is disposed around the substrate 101, it is ensured that the cleaning liquid does not flow out of the cleaning region 501.

In the cleaning process of this embodiment, the surface of the substrate 101 is cleaned under the control by the cleaning control section 431. Specifically, the surface of the substrate 101 is cleaned, under the control that the force of the cleaning liquid acting on the surface of the substrate 101 during cleaning becomes larger than the force of the immersion liquid acting on the surface of the substrate 101 during immersion exposure. More specifically, the surface of the substrate 101 is cleaned, under the control that a shear stress acting on an interface between the cleaning liquid and the substrate 101 during cleaning becomes larger than a shear stress acting on an interface between the immersion liquid and substrate 101 during immersion exposure. In the case of FIG. 1A or 1B, since the resist layer 121 is exposed on the surface of the substrate 101, the surface of the resist layer 121 is cleaned by the cleaning. In the case of FIG. 1C or 1D, since the cover layer 131 is exposed on the surface of the substrate 101, the surface of the cover layer 131 is cleaned by the cleaning.

As described above, in the cleaning process of this embodiment, the force of the cleaning liquid (shear stress of the cleaning liquid) is controlled so as to become larger than the force of the immersion liquid (shear stress of the immersion liquid). This reduces, in the immersion exposure process of this embodiment, the possibility that the exposure machine 301 is contaminated with substances washed by the immersion liquid. This is because the impact given by the cleaning liquid on the substrate surface becomes greater than the impact given by the immersion liquid on the substrate surface during immersion exposure.

The above-described cleaning machine 401 is suitable for such a cleaning process. This is because, with the above-described cleaning machine 401, it is relatively easy to carry out such control that makes the force of the cleaning liquid larger than the force of the immersion liquid. Specific examples of such control will be described below. The exposure machine 301 will be described based on FIGS. 5X and 5Y. The cleaning machine 401 will be described based on FIGS. 6X and 6Y.

In the cleaning process of this embodiment, the following setting is performed. First, the thickness of the cleaning liquid is set so that the thickness of the cleaning liquid between the substrate 101 and the cleaning jig 421 becomes smaller than the thickness of the immersion liquid between the substrate 101 and the immersion exposure jig 321. That is, the thickness “d” shown in FIG. 6X is set to be smaller than the thickness “D” shown in FIG. 5X. Second, the moving speed of the cleaning jig 421 is set so that the relative speed between the cleaning liquid and the substrate 101 becomes substantially the same as the relative speed between the cleaning liquid and the substrate 101.

Now, the relative speed between the immersion liquid and the substrate 101 will be considered. First, a case where the immersion exposure jig 321 is stationary on the substrate 101 is supposed, and the flow of the immersion liquid that occurs in this case will be considered. In this case, if it is supposed that the immersion liquid flows from the center of the immersion region 201 to the periphery, the flow of the immersion liquid becomes slow gradually by an increase in diameter, as the flow moves from the center toward the periphery. Therefore, in this case, the flow velocity of the immersion liquid at the center of the immersion region 201 becomes a maximum flow velocity of the immersion liquid, and becomes a maximum relative speed between the immersion liquid and the substrate 101. This maximum flow velocity is denoted by “v”. The flow velocity of the immersion liquid is expressed by “Q/S” [m/s], by using the supply rate of the immersion liquid “Q” [m³/s], and a flow velocity cross section orthogonal to the flow of the immersion liquid “S” [m²]. A maximum flow velocity “v” generally becomes the flow velocity of a portion having the smallest flow velocity cross section “S”. Next, to generalize this consideration, a case where the immersion exposure jig 321 is moving on the substrate 101 is supposed. It is supposed that the maximum moving speed of the immersion exposure jig 321 is “V”. In this case, the maximum relative speed between the immersion liquid and the substrate 101 becomes “v+V”.

The moving speed of the cleaning jig 421 is set based on the maximum relative speed “v+V” between the immersion liquid and the substrate 101. The method of setting the moving speed of the cleaning jig 421 is shown in FIG. 8. FIG. 8 is a top view for explaining the moving speed of the cleaning jig 421. In the following, the moving speed of the cleaning jig 421 is denoted by “B”.

FIG. 8 shows the flow direction of the cleaning liquid, and the flow velocity of the cleaning liquid “a”. The flow velocity “a” is expressed by “q/s” [m/s], by using the supply rate of the cleaning liquid “q” [m³/s], and a flow velocity cross section orthogonal to the flow of the cleaning liquid “s” [m²]. In the cleaning process of this embodiment, the moving speed “B” of the cleaning jig 421 is set as follows. The following moving speed “B” is an example of the moving speed in a case where the cleaning liquid is held by the cleaning jig 421. When the moving direction of the cleaning jig 421 and the flow direction of the cleaning liquid are the same direction, the relative speed between the cleaning liquid and the substrate 101 becomes “B+a”. In this case, the moving speed of the cleaning jig 421 is set as “B=v+V−a”, to make the relative speed “B+a” equal to the maximum relative speed “v+V”. On the other hand, when the moving direction of the cleaning jig 421 and the flow direction of the cleaning liquid are inverse directions, the relative speed between the cleaning liquid and the substrate 101 becomes “B−a”. In this case, the moving speed of the cleaning jig 421 is set as “B=v+V+a”, to make the relative speed “B−a” equal to the maximum relative speed “v+V”. Further, when the moving direction of the cleaning jig 421 and the flow direction of the cleaning liquid are orthogonal directions, the relative speed between the cleaning liquid and the substrate 101 becomes “B”. In this case, the moving speed of the cleaning jig 421 is set as “B=v+V”, to make the relative speed “B” equal to the maximum relative speed “v+V”. In all of these cases, the relative speed between the cleaning liquid and the substrate 101 becomes “v+V”. That is, the relative speed between the cleaning liquid and the substrate 101 becomes the same speed as the relative speed between the immersion liquid and the substrate 101 (more specifically, the maximum relative speed between the immersion liquid and the substrate 101).

As described above, in the cleaning process of this embodiment, the cleaning is performed by using the cleaning jig 421 capable of moving on the substrate 101, and the moving speed “B” of the cleaning jig 421 is set based on the maximum relative speed “v_{MAX}” (=v+V) between the immersion liquid and the substrate 101, the flow velocity “a” of the cleaning liquid, and the relation between the moving direction of the cleaning jig 421 and the flow direction of the cleaning liquid. In this embodiment, since the cleaning liquid supplying section 422 and the cleaning liquid removing section 423 are provided in the bottom surface of the cleaning jig 421, the cleaning jig 421 can efficiently supply a cleaning liquid between the top surface of the substrate 101 and the bottom surface of the cleaning jig 421, and can efficiently remove the cleaning liquid. Furthermore, in this embodiment, since the cleaning liquid supplying section 422 and the cleaning liquid removing section 423 have strip-like shapes and are disposed parallel to each other, the cleaning jig 421 can cause a cleaning liquid to flow widely between the top surface of the substrate 101 and the bottom surface of the cleaning jig 421.

In the cleaning process of this embodiment, the cleaning of the surface of the substrate 101 is then performed based on the setting as described above. In this embodiment, the thickness “d” of the cleaning liquid is made smaller than the thickness “D” of the immersion liquid. For this reason, in this embodiment, the force of the cleaning liquid is stronger than the force of the immersion liquid, and hence it might be thought that the meniscus action that occurs due to the movement of the cleaning jig 421 is stronger than the meniscus action that occurs due to the movement of the immersion exposure jig 321. This can be verified, for example, by scattering true sphere beads of polyethylene and the like on the substrate 101, and making a comparison between the removal rate of the beads obtained when the cleaning jig 421 moves and the removal rate of the beads obtained when the immersion exposure jig 321 moves.

In this embodiment, when the meniscus action during cleaning is strong, reducing the flow velocity of the cleaning liquid is allowed. This is because when the meniscus action during cleaning is strong, a sufficient cleaning effect is obtained even with a cleaning liquid of a low flow velocity. In determining the value of flow velocity of the cleaning liquid, it is useful to quantitatively evaluate the intensity of the meniscus action. The intensity of the meniscus action can be quantitatively evaluated, for example, from the removal rate of the beads. In this case, the value of flow velocity of the cleaning liquid can be determined according to the intensity of the meniscus action. Since the flow velocity of the cleaning liquid depends on the condition of the substrate surface, it is desirable to optimize the flow velocity of the cleaning liquid in consideration of the condition of the substrate surface.

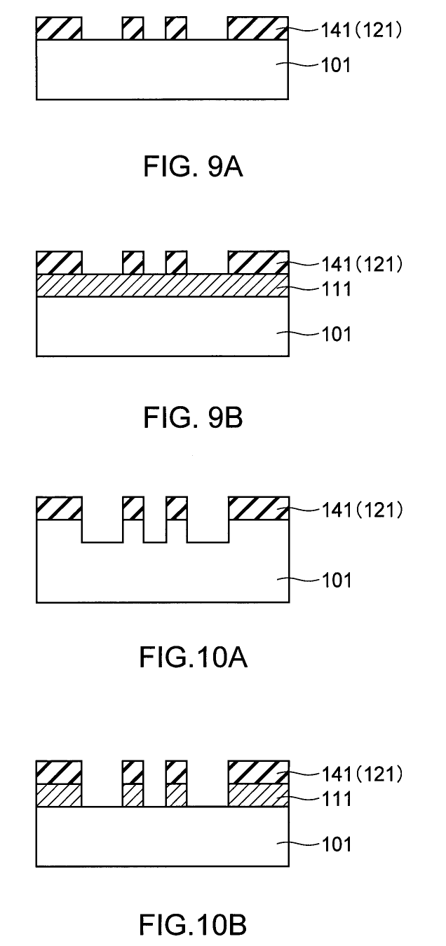

FIGS. 9A and 9B are cross-sectional views of the substrate (wafer substrate) 101. In the pattern forming method of this embodiment, the development process is performed after the cleaning process and the liquid immersion process. In the development process of this embodiment, the resist layer 121 is developed to form a resist pattern 141 on the substrate 101. That is, the resist layer 121 is processed into the resist pattern 141.

In FIG. 9A, the substrate 101 of FIG. 1A or 1C after development is shown. The substrate 101 of FIG. 1C is changed to the substrate 101 of FIG. 4A due to removing the cover layer 131, and is changed to the substrate 101 of FIG. 9A due to developing the resist layer 121.

In FIG. 9B, the substrate 101 of FIG. 1B or 1D after development is shown. The substrate 101 of FIG. 1D is changed to the substrate 101 of FIG. 4B due to removing the cover layer 131, and is changed to the substrate 101 of FIG. 9B due to developing of the resist layer 121.

The pattern forming method of this embodiment is applicable to a method of manufacturing a semiconductor device. In FIG. 9A, for example, a trench of an isolation layer can be formed by etching the substrate 101 by using the resist pattern 141 as a mask (FIG. 10A). In FIG. 9B, for example, a gate electrode, a contact hole, a via hole, or a trench for a line can be formed by etching the layer 111 by using the resist pattern 141 as a mask (FIG. 10B). In FIG. 9B, the layer 111 and the substrate 101 may be etched by using the resist pattern 141 as a mask.

As described above, in the cleaning of this embodiment, the surface of the substrate 101 is cleaned, under a control that a shear stress acting on an interface between the cleaning liquid and the substrate 101 during cleaning becomes larger than a shear stress acting on an interface between the immersion liquid and the substrate 101 during immersion exposure. Such control will be further explained below.

As described above, the flow velocity of the cleaning liquid “a” is expressed by “q/s” [m/s], by using the supply rate of the cleaning liquid “q” [m³/s], and the flow velocity cross section orthogonal to the flow of the cleaning liquid “s” [m²]. Similarly, the flow velocity of the immersion liquid is expressed by “Q/S” [m/s], by using the supply rate of the immersion liquid “Q” [m³/s], and the flow velocity cross section orthogonal to the flow of the immersion liquid “S” [m²]. A maximum value of the flow velocity “Q/S” is a maximum flow velocity “v”. If the supply rate “Q” of the immersion liquid is constant, the flow velocity “Q/S” of a portion where the flow velocity cross section “S” becomes the minimum between upstream and downstream of the immersion liquid, becomes a maximum flow velocity “v”.

In the cleaning process of this embodiment, for example, the surface of the substrate 101 may be cleaned, under a control that the thickness of the cleaning liquid existing between the substrate 101 and the cleaning jig 421 during cleaning becomes smaller than the thickness of the immersion liquid existing between the substrate 101 and the immersion exposure jig 321 during immersion exposure. This is because the cleaning effect of the cleaning liquid is improved by making the thickness of the cleaning liquid small. In the cleaning process of this embodiment, for example, the thickness “d” of the cleaning liquid is made smaller than the thickness “D” of the immersion liquid, with the relative speed between the cleaning liquid and the substrate 101 kept equal to the relative speed between the immersion liquid and the substrate 101. Thereby, the force of the cleaning liquid becomes larger than the force of the immersion liquid. This is the same as the specific example explained in FIG. 8.

In the cleaning process of this embodiment, for example, the surface of the substrate 101 may be cleaned, under a control that the relative speed between the cleaning liquid and the substrate 101 during cleaning becomes larger than the relative speed between the immersion liquid and the substrate 101 during immersion exposure. This is because the cleaning effect of the cleaning liquid is improved by increasing the relative speed between the cleaning liquid and the substrate 101. In the cleaning process of this embodiment, for example, the relative speed between the cleaning liquid and the substrate 101 is made faster than the relative speed between the immersion liquid and the substrate 101, with the thickness “d” of the cleaning liquid kept equal to the relative thickness “D” of the immersion liquid. Thereby, the force of the cleaning liquid becomes larger than the force of the immersion liquid. In FIG. 8, the relative speed between the cleaning liquid and the substrate 101 becomes larger than “v+V” by replacing B=v+V−a, B=v+V+a, and B=v+V with B>v+V−a, B>v+V+a, and B>v+V respectively. That is, the relative speed between the cleaning liquid and the substrate 101 becomes faster than the relative speed between the immersion liquid and the substrate 101 (more specifically, the maximum relative speed between the immersion liquid and the substrate 101).

In the cleaning process of this embodiment, for example, it is also possible to make the thickness “d” of the cleaning liquid smaller than the thickness “D” of the immersion liquid, and simultaneously to make the relative speed between the cleaning liquid and the substrate 101 faster than the relative speed between the immersion liquid and the substrate 101. This enables the force of the cleaning liquid to be made substantially larger than the force of the immersion liquid.

On the other hand, in the cleaning process of this embodiment, it is possible to make the thickness “d” of the cleaning liquid larger than the thickness “D” of the immersion liquid. In this case, decrease in the speed of the cleaning liquid is caused by making the thickness of the cleaning liquid larger. This is because, as described above, the speed of the cleaning liquid is expressed by “q/s” by using the supply rate “q” of the cleaning liquid and the flow velocity cross section “s” orthogonal to the flow of the cleaning liquid. Therefore, in this case, to ensure that the decrease in speed caused by making the thickness of the cleaning liquid larger is sufficiently compensated, the supply speed and removal speed of the cleaning liquid are sufficiently increased, thereby the relative speed between the cleaning liquid and the substrate 101 is sufficiently made faster than the relative speed between the immersion liquid and the substrate 101. That is, since the thickness becomes d/D times, the relative speed is made larger than d/D times. This enables the force of the cleaning liquid to be made larger than the force of the immersion liquid.

The fact that a speed change in the cleaning liquid is caused by a change in the thickness of the cleaning liquid can pose a problem in any of the above-described cleaning processes. Therefore, it is desirable to appropriately set the supply speed and removal speed of the cleaning liquid in order to ensure a desired speed of the cleaning liquid. In addition, it is desirable to appropriately set the moving speed “B” of the cleaning jig 421. In this manner, it is possible to make the force of the cleaning liquid larger than the force of the immersion liquid.

In this embodiment, the relative speed between the cleaning liquid and the substrate 101 is a relative speed at an interface between the cleaning liquid and the substrate 101. This is because, in this embodiment, the magnitude of shear stress acting on an interface between the cleaning liquid and the substrate 101 is important. Further, in this embodiment, the relative speed between the immersion liquid and the substrate 101 is a relative speed at an interface between the immersion liquid and the substrate 101. This is because, in this embodiment, the magnitude of shear stress acting on an interface between the immersion liquid and the substrate 101 is important. Further, in this embodiment, the relative speed between the immersion liquid and the substrate 101 is a maximum relative speed between the immersion liquid and the substrate 101. In this case, the relative speed between the cleaning liquid and the substrate 101 is made faster than a maximum relative speed between the immersion liquid and the substrate 101, thereby the relative speed between the cleaning liquid and the substrate 101 becomes constantly faster than the relative speed between the immersion liquid and the substrate 101.

Although the cleaning liquid and the immersion liquid are the same liquid here, the cleaning liquid and the immersion liquid may be different liquids. When substances adhered to the substrate surface, which are to be cleaned, are organic substances, it is preferred that the cleaning liquid be an oxidizing liquid. Examples of such a liquid include ozone water and hydrogen peroxide water. Photoacid generators and dissolution inhibitors that segregate in the surface layer of the resist layer 121, and contaminations on the cover layer 131, are removed by a stronger cleaning action of such a liquid. A similarly strong removal action is obtained also by using carbonic acid water that is effective in canceling out the electric charges included in contaminations and particles.

The resist layer 121 may be a chemically amplified resist layer, or may also be a resist layer except a chemically amplified type. However, the cleaning process of this embodiment is particularly effective in the cleaning of the chemically amplified resist layer. This is because contaminations tend to become a problem particularly for the chemically amplified resist layer. According to the cleaning method of this embodiment, the occurrence of contaminations in the chemically amplified resist layer is efficiently suppressed.

In this embodiment, as an example of a method of evaluating the cleaning action, an experiment using true sphere beads was mentioned. However, other evaluation methods by which the cleaning action is quantitatively evaluated may be adopted for evaluating the cleaning action. The above-described thickness and relative speed can be appropriately set by using such evaluation methods.

Various methods are conceivable as a technique for controlling the relative speed between the cleaning liquid and the substrate 101. It is possible to use, for example, a jet nozzle having a flat opening and capable of controlling the thickness. In such a case, it is possible to adopt a method that includes supplying the cleaning liquid from the jet nozzle to the surface of the substrate 101 at a desired flow velocity with the substrate 101 rotated, and causing the nozzle to scan in a radial direction of the substrate 101.

The cleaning process of this embodiment may be carried out by using a cleaning machine other than the above-described cleaning machine 401. The cleaning process of this embodiment may be carried out, for example, by usual rotary cleaning. In this case, it is possible to control the thickness “d” of the cleaning liquid and the relative speed between the cleaning liquid and the substrate 101 by controlling, for example, the rotation speed and the supplied amount of cleaning liquid. In this case, however, the thickness “d” does not denote the thickness of the cleaning liquid existing between the substrate 101 and the cleaning jig 421, but denotes, more generally, the thickness of a layer of the cleaning liquid formed on the substrate 101.

As described above, according to the embodiments of the present invention, it is possible to provide a method of forming a pattern, a method of manufacturing a semiconductor device, and a cleaning apparatus, which enable a substrate surface to be advantageously cleaned.

1. A method of forming a pattern, the method comprising:
forming a resist layer on a substrate;
cleaning a surface of the substrate under a control that a shear stress acting on an interface between a cleaning liquid and the substrate during the cleaning becomes larger than a shear stress acting on an interface between an immersion liquid and the substrate during immersion exposure;
exposing the resist layer by the immersion exposure to form a latent image on the resist layer; and
developing the resist layer to form a resist pattern on the substrate.

2. The method according to claim 1, wherein,
the cleaning is performed under the control that the thickness of a layer of the cleaning liquid formed on the substrate during the cleaning becomes smaller than the thickness of the immersion liquid existing between the substrate and an immersion exposure jig during the immersion exposure.

3. The method according to claim 1, wherein,
the cleaning is performed under the control that the relative speed between the cleaning liquid and the substrate during the cleaning becomes larger than the relative speed between the immersion liquid and the substrate during the immersion exposure.

4. The method according to claim 1, wherein,
the cleaning is performed by using a cleaning jig capable of moving on the substrate, and
the moving speed of the cleaning jig is set based on a maximum relative speed between the immersion liquid and the substrate during the immersion exposure, the flow velocity of the cleaning liquid during the cleaning, and a relation between the moving direction of the cleaning jig and the flow direction of the cleaning liquid.

5. The method according to claim 2, wherein,
the cleaning is performed by using a cleaning jig capable of moving on the substrate, and
when the moving direction of the cleaning jig and the flow direction of the cleaning liquid are the same direction, the moving speed of the cleaning jig is set as B=v_{MAX}−a,
when the moving direction of the cleaning jig and the flow direction of the cleaning liquid are inverse directions, the moving speed of the cleaning jig is set as B=v_{MAX}+a, and
when the moving direction of the cleaning jig and the flow direction of the cleaning liquid are orthogonal directions, the moving speed of the cleaning jig is set as B=v_{MAX},
where “B” denotes the moving speed of the cleaning jig, “v_{MAX}” denotes a maximum relative speed between the immersion liquid and the substrate during the immersion exposure, and “a” denotes the flow velocity of the cleaning liquid during the cleaning.

6. The method according to claim 3, wherein,
the cleaning is performed by using a cleaning jig capable of moving on the substrate, and
when the moving direction of the cleaning jig and the flow direction of the cleaning liquid are the same direction, the moving speed of the cleaning jig is set as B>v_{MAX}−a,
when the moving direction of the cleaning jig and the flow direction of the cleaning liquid are inverse directions, the moving speed of the cleaning jig is set as B>v_{MAX}+a, and
when the moving direction of the cleaning jig and the flow direction of the cleaning liquid are orthogonal directions, the moving speed of the cleaning jig is set as B>v_{MAX},
where “B” denotes the moving speed of the cleaning jig, “v_{MAX}” denotes a maximum relative speed between the immersion liquid and the substrate during the immersion exposure, and “a” denotes the flow velocity of the cleaning liquid during the cleaning.

7. The method according to claim 1, wherein an application layer is formed on the resist layer before the cleaning, and the application layer is removed after the immersion exposure.

8. The method according to claim 1, wherein,
the cleaning is performed under the control that the thickness of a layer of the cleaning liquid formed on the substrate during the cleaning becomes smaller than the thickness of the immersion liquid existing between the substrate and an immersion exposure jig during the immersion exposure, and that the relative speed between the cleaning liquid and the substrate during the cleaning becomes larger than the relative speed between the immersion liquid and the substrate during the immersion exposure.

9. The method according to claim 1, wherein,
the cleaning is performed under the control that the thickness of a layer of the cleaning liquid formed on the substrate during the cleaning becomes larger than the thickness of the immersion liquid existing between the substrate and an immersion exposure jig during the immersion exposure, and that the relative speed between the cleaning liquid and the substrate during the cleaning becomes larger than the relative speed between the immersion liquid and the substrate during the immersion exposure.

10. The method according to claim 1, wherein the cleaning liquid is pure water, ozone water, or hydrogen peroxide water.

11. The method according to claim 1, wherein the resist layer is a chemically amplified resist layer.

12. A method of manufacturing a semiconductor device, the method comprising:
forming a resist layer on a substrate;
cleaning a surface of the substrate under a control that a shear stress acting on an interface between a cleaning liquid and the substrate during the cleaning becomes larger than a shear stress acting on an interface between an immersion liquid and the substrate during immersion exposure;
exposing the resist layer by the immersion exposure to form a latent image on the resist layer;
developing the resist layer to form a resist pattern on the substrate; and
processing, using the resist pattern, the substrate or/and a layer to be processed existing between the substrate and the resist pattern.

13. The method according to claim 12, wherein,
the cleaning is performed under the control that the thickness of a layer of the cleaning liquid formed on the substrate during the cleaning becomes smaller than the thickness of the immersion liquid existing between the substrate and an immersion exposure jig during the immersion exposure.

14. The method according to claim 12, wherein,
the cleaning is performed under the control that the relative speed between the cleaning liquid and the substrate during the cleaning becomes larger than the relative speed between the immersion liquid and the substrate during the immersion exposure.

15. The method according to claim 12, wherein,
the cleaning is performed by using a cleaning jig capable of moving on the substrate, and
the moving speed of the cleaning jig is set based on a maximum relative speed between the immersion liquid and the substrate during the immersion exposure, the flow velocity of the cleaning liquid during the cleaning, and a relation between the moving direction of the cleaning jig and the flow direction of the cleaning liquid.

16. A cleaning apparatus comprising:
a cleaning jig for cleaning a surface of a substrate with a cleaning liquid;
a cleaning liquid supplying section provided in the cleaning jig and configured to supply the cleaning liquid;
a cleaning liquid removing section provided in the cleaning jig and configured to remove the cleaning liquid; and
a cleaning control section configured to clean the surface of the substrate, by relatively moving the substrate and the cleaning jig under a condition that the cleaning liquid exists between the substrate and the cleaning jig.

17. The apparatus according to claim 16, wherein the cleaning liquid supplying section and the cleaning liquid removing section are provided on a bottom surface of the cleaning jig.

18. The apparatus according to claim 16, wherein the cleaning liquid supplying section and the cleaning liquid removing section have strip-like shapes and are disposed in parallel to each other.

19. The apparatus according to claim 16, further comprising:
a cleaning stage for holding the substrate; and
an auxiliary cleaning stage disposed around the substrate.

20. The apparatus according to claim 16, wherein,
the cleaning control section sets the moving speed of the cleaning jig based on a maximum relative speed between the immersion liquid and the substrate during the immersion exposure, the flow velocity of the cleaning liquid during the cleaning, and a relation between the moving direction of the cleaning jig and the flow direction of the cleaning liquid.
